(19) United States
(12) Patent Application Publication
(10) Pub. No.: US 2026/0150644 A1
(43) Pub. Date: May 28, 2026

(54) ELECTROMAGNETICALLY SHIELDED STACKED TRANSISTOR ARCHITECTURE

(71) Applicant: International Business Machines Corporation, Armonk, NY (US)

(72) Inventors: Darsith Jayachandran, Menands, NY (US); Ruilong Xie, Niskayuna, NY (US); Koichi Motoyama, Clifton Park, NY (US); Nicholas Anthony Lanzillo, Wynantskill, NY (US); Julien Frougier, Albany, NY (US); Nicolas Jean Loubet, Guilderland, NY (US)

(21) Appl. No.: 18/958,135

(22) Filed: Nov. 25, 2024

(51) Int. Cl. H01L 23/522; H01L 21/762; H01L 23/528; H01L 23/532

(52) U.S. Cl. CPC H10W 20/423; H10D 64/018; H10D 84/0193; H10D 84/038; H10D 84/834; H10W 10/014; H10W 10/17; H10W 20/427; H10W 20/435; H10W 20/4462

(57) ABSTRACT

A semiconductor device includes a bottom transistor, a top transistor vertically stacked over the bottom transistor, and a bonding structure disposed between the bottom transistor and the top transistor. The bonding structure includes an electromagnetic shield layer. The semiconductor device further includes at least one peripheral contact positioned peripherally to the bottom transistor and the top transistor and extending through the bonding structure. The at least one peripheral contact is isolated from the electromagnetic shield layer of the bonding structure by one or more gate inner spacers.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Embodiments described herein provide techniques for forming an electromagnetically shielded stacked transistor architecture.

In one embodiment, a semiconductor device includes a bottom transistor, a top transistor vertically stacked over the bottom transistor, and a bonding structure disposed between the bottom transistor and the top transistor. The bonding structure includes an electromagnetic shield layer. The semiconductor device further includes at least one peripheral contact positioned peripherally to the bottom transistor and the top transistor and extending through the bonding structure. The at least one peripheral contact is isolated from the electromagnetic shield layer of the bonding structure by one or more gate inner spacers.

In another embodiment, a semiconductor device includes a bottom device level including a first complementary metal-oxide-semiconductor device, a top device level including a second complementary metal-oxide-semiconductor device, and an electromagnetic shield layer positioned between the bottom device level and the top device level. The semiconductor device further includes one or more backside interconnect layers positioned adjacent to the bottom device level, one or more frontside interconnect layers positioned adjacent to the top device level, and at least one peripheral contact extending through the electromagnetic shield layer and connected to at least one of the one or more backside interconnect layers and at least one of the one or more frontside interconnect layers.

In yet another embodiment, a method includes forming a bottom transistor, forming a bonding structure over the bottom transistor, where the bonding structure includes an electromagnetic shield layer disposed between one or more bonding layers. The method further includes forming a top transistor over the bonding structure and forming at least one peripheral contact positioned peripherally to the bottom transistor and the top transistor and extending through the bonding structure, where the at least one peripheral contact is isolated from the electromagnetic shield layer of the bonding structure by one or more gate inner spacers.

These and other features and advantages of embodiments described herein will become more apparent from the accompanying drawings and the following detailed description.

### BRIEF DESCRIPTION OF THE DRAWINGS

FIG. 1 depicts a top view of a semiconductor structure indicating X, Y1, and Y2 cross-section locations on which the cross-sectional views of FIGS. 2A-15C are based.

FIG. 2A depicts a first cross-sectional view corresponding to the line X in FIG. 1 during an intermediate step of a method of fabricating a nanosheet transistor structure, according to an illustrative embodiment.

FIG. 2B depicts a second cross-sectional view corresponding to the line Y1 in FIG. 1 during the intermediate step of the method of fabricating the nanosheet transistor structure, according to an illustrative embodiment.

FIG. 2C depicts a third cross-sectional view corresponding to the line Y2 in FIG. 1 during the intermediate step of the method of fabricating the nanosheet transistor structure, according to an illustrative embodiment.

FIG. 3A depicts a first cross-sectional view corresponding to the line X in FIG. 1 following dummy gate removal, sacrificial layer removal, and formation of a high-k dielectric layer for a bottom device level, according to an embodiment.

FIG. 3B depicts a second cross-sectional view corresponding to the line Y1 in FIG. 1 following the dummy gate removal, the sacrificial layer removal, and the formation of the high-k dielectric layer for the bottom device level, according to an embodiment.

FIG. 3C depicts a third cross-sectional view corresponding to the line Y2 in FIG. 1 following the dummy gate removal, the sacrificial layer removal, and the formation of the high-k dielectric layer for the bottom device level, according to an embodiment.

FIG. 4A depicts a first cross-sectional view corresponding to the line X in FIG. 1 following formation of reliability layer, a gate cut process, and formation of a bonding layer and an electromagnetic shield layer, according to an embodiment.

FIG. 4B depicts a second cross-sectional view corresponding to the line Y1 in FIG. 1 following the formation of the reliability layer, the gate cut process, and the formation of the bonding layer and the electromagnetic shield layer, according to an embodiment.

FIG. 4C depicts a third cross-sectional view corresponding to the line Y2 in FIG. 1 following the formation of the reliability layer, the gate cut process, and the formation of the bonding layer and the electromagnetic shield layer, according to an embodiment.

FIG. 5A depicts a first cross-sectional view corresponding to the line X in FIG. 1 following bonding of a nanosheet stack including nanosheet channel layers for forming a top device level of the stacked transistor structure, according to an embodiment.

FIG. 5B depicts a second cross-sectional view corresponding to the line Y1 in FIG. 1 following the bonding of the nanosheet stack including the nanosheet channel layers for the top device level of the stacked transistor structure, according to an embodiment.

FIG. 5C depicts a third cross-sectional view corresponding to the line Y2 in FIG. 1 following the bonding of the nanosheet stack including the nanosheet channel layers for the top device level of the stacked transistor structure, according to an embodiment.

FIG. 6A depicts a first cross-sectional view corresponding to the line X in FIG. 1 following formation of the top device level of the stacked transistor structure, according to an embodiment.

FIG. 6B depicts a second cross-sectional view corresponding to the line Y1 in FIG. 1 following the formation of the top device level of the stacked transistor structure, according to an embodiment.

FIG. 6C depicts a third cross-sectional view corresponding to the line Y2 in FIG. 1 following the formation of the top device level of the stacked transistor structure, according to an embodiment.

FIG. 7A depicts a first cross-sectional view corresponding to the line X in FIG. 1 following formation of trenches for middle-of-line (MOL) contacts, according to an embodiment.

FIG. 7B depicts a second cross-sectional view corresponding to the line Y1 in FIG. 1 following the formation of the trenches for the MOL contacts, according to an embodiment.

FIG. 7C depicts a third cross-sectional view corresponding to the line Y2 in FIG. 1 following the formation of the trenches for the MOL contacts, according to an embodiment.

FIG. 8A depicts a first cross-sectional view corresponding to the line X in FIG. 1 following partial removal of the electromagnetic shield layer, according to an embodiment.

FIG. 8B depicts a second cross-sectional view corresponding to the line Y1 in FIG. 1 following the partial removal of the electromagnetic shield layer, according to an embodiment.

FIG. 8C depicts a third cross-sectional view corresponding to the line Y2 in FIG. 1 following the partial removal of the electromagnetic shield layer, according to an embodiment.

FIG. 9A depicts a first cross-sectional view corresponding to the line X in FIG. 1 following spacer formation, according to an embodiment.

FIG. 9B depicts a second cross-sectional view corresponding to the line Y1 in FIG. 1 following the spacer formation, according to an embodiment.

FIG. 9C depicts a third cross-sectional view corresponding to the line Y2 in FIG. 1 following the spacer formation, according to an embodiment.

FIG. 10A depicts a first cross-sectional view corresponding to the line X in FIG. 1 following MOL contact formation, according to an embodiment.

FIG. 10B depicts a second cross-sectional view corresponding to the line Y1 in FIG. 1 following the MOL contact formation, according to an embodiment.

FIG. 10C depicts a third cross-sectional view corresponding to the line Y2 in FIG. 1 following the MOL contact formation, according to an embodiment.

FIG. 11A depicts a first cross-sectional view corresponding to the line X in FIG. 1 following back-end-of-line (BEOL) interconnect formation and carrier wafer bonding, according to an embodiment.

FIG. 11B depicts a second cross-sectional view corresponding to the line Y1 in FIG. 1 following the BEOL interconnect formation and the carrier wafer bonding, according to an embodiment.

FIG. 11C depicts a third cross-sectional view corresponding to the line Y2 in FIG. 1 following the BEOL interconnect formation and the carrier wafer bonding, according to an embodiment.

FIG. 12A depicts a first cross-sectional view corresponding to the line X in FIG. 1 following wafer flipping, semiconductor substrate and etch stop layer removal, and backside gate spacer formation, according to an embodiment.

FIG. 12B depicts a second cross-sectional view corresponding to the line Y1 in FIG. 1 following the wafer flipping, the semiconductor substrate and the etch stop layer removal, and the backside gate spacer formation, according to an embodiment.

FIG. 12C depicts a third cross-sectional view corresponding to the line Y2 in FIG. 1 following the wafer flipping, the semiconductor substrate and the etch stop layer removal, and the backside gate spacer formation, according to an embodiment.

FIG. 13A depicts a first cross-sectional view corresponding to the line X in FIG. 1 following partial removal of the high-k dielectric layer and reliability layer removal, according to an embodiment.

FIG. 13B depicts a second cross-sectional view corresponding to the line Y1 in FIG. 1 following the partial removal of the high-k dielectric layer and the reliability layer removal, according to an embodiment.

FIG. 13C depicts a third cross-sectional view corresponding to the line Y2 in FIG. 1 following the partial removal of the high-k dielectric layer and the reliability layer removal, according to an embodiment.

FIG. 14A depicts a first cross-sectional view corresponding to the line X in FIG. 1 following gate structure formation for the bottom device level, gate structure recessing, capping layer formation, sacrificial placeholder removal, and backside contact formation, according to an embodiment.

FIG. 14B depicts a second cross-sectional view corresponding to the line Y1 in FIG. 1 following the gate structure formation for the bottom device level, the gate structure recessing, the capping layer formation, the sacrificial placeholder removal, and the backside contact formation, according to an embodiment.

FIG. 14C depicts a third cross-sectional view corresponding to the line Y2 in FIG. 1 following the gate structure formation for the bottom device level, the gate structure recessing, the capping layer formation, the sacrificial placeholder removal, and the backside contact formation, according to an embodiment.

FIG. 15A depicts a first cross-sectional view corresponding to the line X in FIG. 1 following backside BEOL interconnect formation, according to an embodiment.

FIG. 15B depicts a second cross-sectional view corresponding to the line Y1 in FIG. 1 following the backside BEOL interconnect formation, according to an embodiment.

FIG. 15C depicts a third cross-sectional view corresponding to the line Y2 in FIG. 1 following the backside BEOL interconnect formation, according to an embodiment.

### DETAILED DESCRIPTION

Illustrative embodiments may be described herein in the context of illustrative methods for forming an electromagnetically shielded stacked transistor architecture, along with illustrative apparatus, systems, and devices formed using such methods. However, it is to be understood that embodiments described herein are not limited to the illustrative methods, apparatus, systems, and devices but instead are more broadly applicable to other suitable methods, apparatus, systems, and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A FET is a three-terminal device having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the area of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm node and beyond. A general process flow for formation of a nanosheet stack involves removing sacrificial layers, which may be formed of silicon germanium (SiGe), between sheets of channel material, which may be formed of silicon (Si).

For continued scaling and area improvement, stacked transistor structures may be used. A stacked transistor structure may include multiple transistors stacked over one another vertically. With stacked transistor structures, for example, vias which extend between the frontside and the backside may have a high aspect ratio. The formation of high aspect ratio vias, however, presents various process challenges.

Stacked transistor structures may utilize sequential integration fabrication processes. Sequential integration includes forming “bottom” transistors of a stacked transistor structure, followed by wafer bonding and formation of “top” transistors of the stacked transistor structure. The bottom and top transistors of the stacked transistor structure may also be referred to as being different “levels” of the stacked transistor structure (e.g., where the bottom transistors are a bottom device level of the stacked transistor structure and the top transistors are a top device level of the stacked transistor structure). Sequential integration fabrication processes provide various advantages relative to monolithic fabrication processes. For example, sequential integration allows for: an increased effective width (Weff) with the same device footprint; increasing the number of channels (e.g., nanosheet channels); and further critical dimension (CD) scaling. Since the top and bottom device levels are integrated separately, sequential integration allows for unique transistor architectures (e.g., shifted, staggered, etc.), split gate schemes, multiple threshold voltage (multi-Vt) replacement metal gate (RMG) learning from nanosheets, channel engineering for the top and bottom device levels (e.g., mobility), and reduced process complexity.

Stacked transistor structures can utilize different architectures. One example is a “stepped” architecture, where the nanosheet channels of the top transistors are narrower than those of the bottom transistors. Another is an “aligned” architecture, where the nanosheet channels of the top and bottom transistors are the same size and are aligned. However, stacked transistors can increase electromagnetic interference between the top and bottom layers of devices. This interference is exacerbated when power distribution and signal lines are routed above the top layer and below the bottom layer.

Embodiments described herein provide electromagnetically shielded stacked transistor structures that advantageously address critical issues related to electromagnetic interference (e.g., in stacked CMOS transistors). For example, one or more embodiments can integrate a graphene layer as an electromagnetic shield within the bonding oxide between the top and bottom levels of transistors, thereby significantly reducing electromagnetic interference without interrupting connections between higher level backside BEOL interconnects and frontside BEOL interconnects.

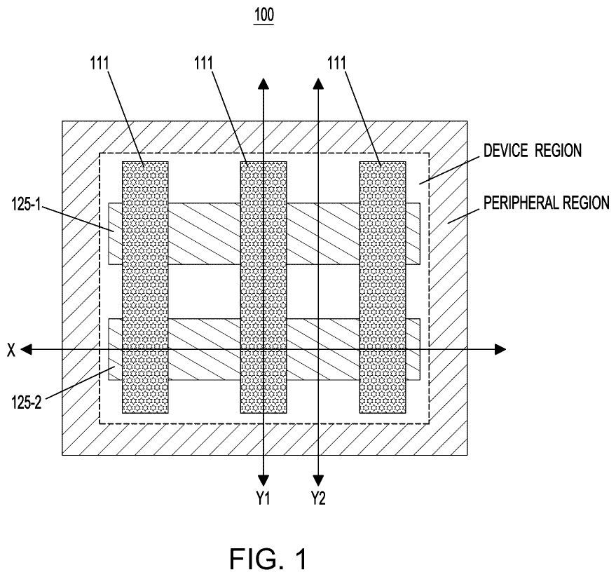

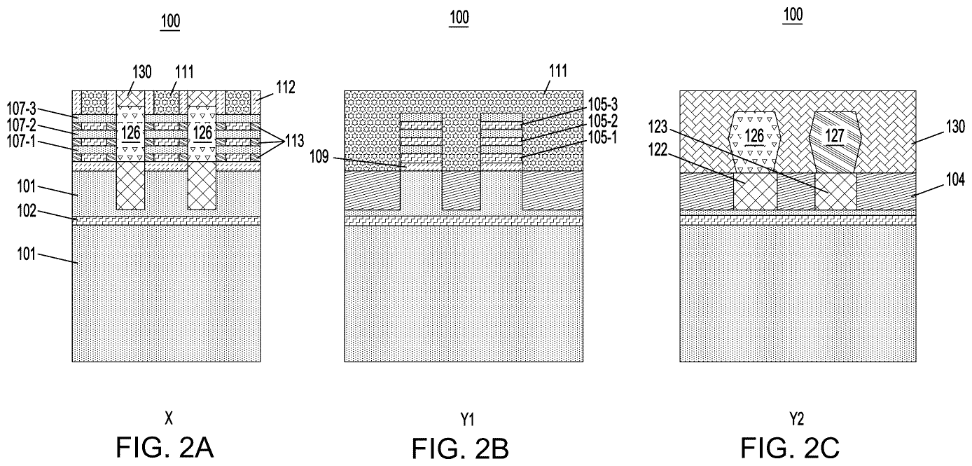

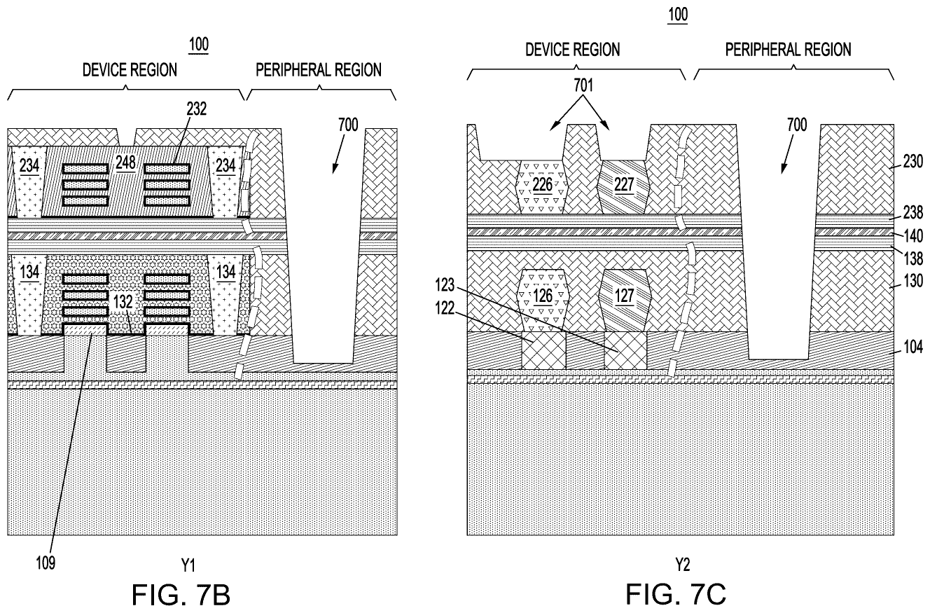

FIG. 1 depicts a top view of a semiconductor structure 100 indicating X, Y1, and Y2 cross-section locations on which the cross-sectional views of FIGS. 2A-15C are based, according to an illustrative embodiment. The semiconductor structure 100 includes dummy gate portions 111 and active regions 125-1 and 125-2 (collectively “active regions 125”). The dummy gate portions 111 correspond to areas of the semiconductor structure 100 where gate structures 148 are formed, and the active regions 125 correspond to areas of the semiconductor structure 100 where source/drain regions 126 and 127 are formed, as described in more detail herein. In some embodiments, the active region 125-1 may correspond to an n-type transistor and the active region 125-2 may correspond to a p-type transistor. FIG. 1 also shows a device region and a peripheral region, which are described in more detail in conjunction with FIGS. 7B-15C. Generally, the device region of the semiconductor structure 100 corresponds to where core devices (e.g., transistors) of the semiconductor structure 100 are positioned, and the peripheral region corresponds to an area surrounding the device region.

Referring to FIG. 1 and to the cross-sectional views in FIGS. 2A-2C, which correspond respectively to the lines X, Y1, and Y2 in FIG. 1, the semiconductor structure 100 includes a semiconductor substrate 101 and an etch stop layer 102 formed in the semiconductor substrate 101.

The semiconductor substrate 101 may be formed of any suitable semiconductor material, including various silicon-containing materials such as Si, SiGe, silicon germanium carbide (SiGeC), silicon carbide (SiC) and multi-layers thereof. Although silicon is the predominantly used semiconductor material in wafer fabrication, alternative semiconductor materials can be employed as additional layers, such as, but not limited to, germanium (Ge), gallium arsenide (GaAs), gallium nitride (GaN), SiGe, cadmium telluride (CdTe), and zinc selenide (ZnSe).

The etch stop layer 102 may comprise a buried oxide (BOX) layer or SiGe, or another suitable material such as a III-V semiconductor epitaxial layer.

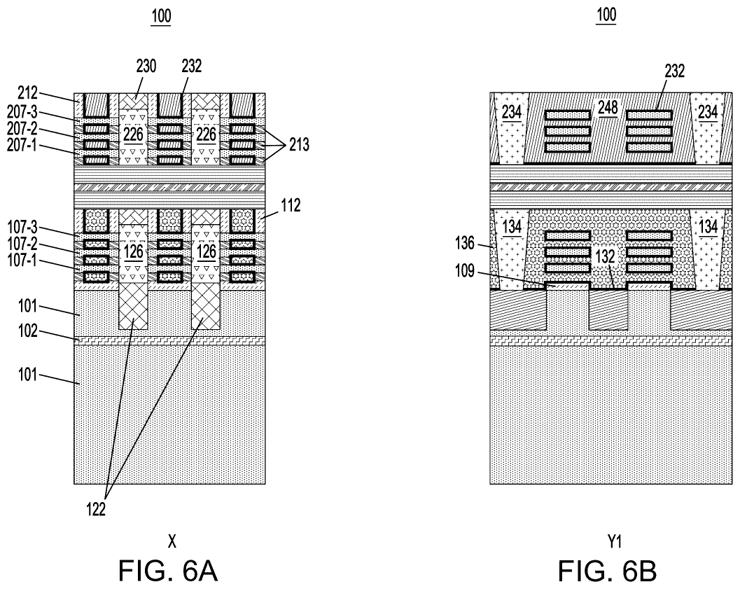

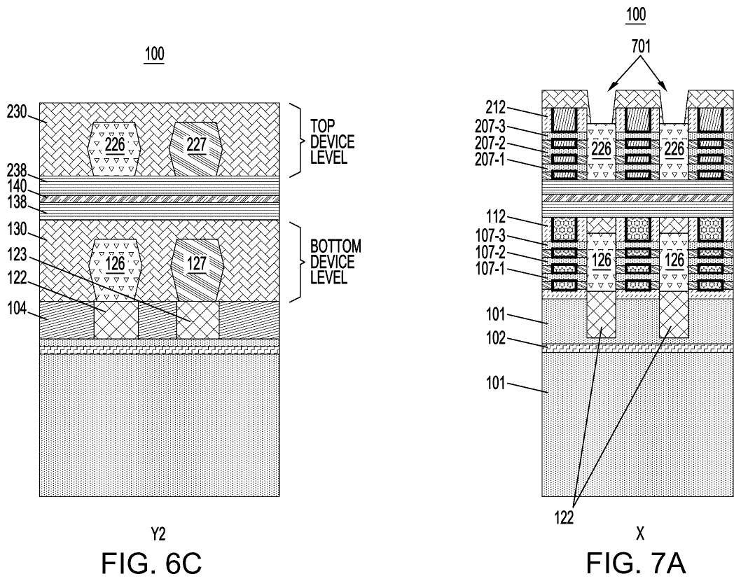

The semiconductor structure 100 also includes a stacked structure of bottom sacrificial layers 105-1, 105-2, and 105-3 (collectively “bottom sacrificial layers 105”), bottom channel layers 107-1, 107-2, and 107-3 (collectively “bottom channel layers 107”), and a bottom dielectric isolation (BDI) layer 109. The stacked structure of the bottom sacrificial layers 105 and the bottom channel layers 107 are associated with a bottom device level (see, e.g., FIGS. 6A-6C).

In an illustrative embodiment, the bottom channel layers 107 comprise silicon. In an illustrative embodiment, the bottom sacrificial layers 105 comprise silicon germanium (SiGe) and the bottom channel layers 107 comprise silicon. In illustrative embodiments, the bottom sacrificial layers 105 comprise a germanium concentration of about 30% (e.g., SiGe30), but the embodiments are not necessarily limited to SiGe30 for the bottom sacrificial layers 105. The BDI layer 109 may comprise, for example, silicon oxide (SiOₓ) (where x is, for example, 2, 1.99 or 2.01), silicon oxycarbide (SiOC), silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN), and combinations thereof.

While three bottom sacrificial layers 105 and three bottom channel layers 107 are shown, the embodiments are not necessarily limited to the shown number of sacrificial layers 105 and channel layers 107, and there may be more or fewer layers in the same alternating configuration depending on design constraints. Additionally, although SiGe is described as a sacrificial material for bottom sacrificial layers 105, other materials can be used as long as the bottom sacrificial layers 105 have the property of being able to be removed selectively compared to the material of the bottom channel layers 107.

According to one or more embodiments, the bottom sacrificial layers 105 and the bottom channel layers 107 are epitaxially grown in an alternating and stacked configuration on the semiconductor substrate 101. For example, the bottom sacrificial layer 105-1 is followed by the bottom channel layer 107-1 on the bottom sacrificial layer 105-1, which is followed by the bottom sacrificial layer 105-2 on the first bottom channel layer 107-1, and so on. As can be understood, the bottom sacrificial layers 105 and the bottom channel layers 107 are epitaxially grown from their corresponding underlying semiconductor layers.

The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The epitaxial deposition process may employ the deposition chamber of a chemical vapor deposition (CVD) type apparatus, such as a metal-organic chemical vapor deposition (MOCVD), rapid thermal chemical vapor deposition (RTCVD), ultra-high vacuum chemical vapor deposition (UHVCVD), or a low-pressure chemical vapor deposition (LPCVD) apparatus. A number of different sources may be used for the epitaxial deposition of the in situ doped semiconductor material. In some embodiments, the gas source for the deposition of an epitaxially formed semiconductor material may include silicon (Si) deposited from silane, disilane, trisilane, tetrasilane, hexachlorodisilane, tetrachlorosilane, dichlorosilane, trichlorosilane, and combinations thereof. In other examples, when the semiconductor material includes germanium, a germanium gas source may be selected from the group consisting of germane, digermane, halogermane, dichlorogermane, trichlorogermane, tetrachlorogermane and combinations thereof. The temperature for epitaxial deposition typically ranges from 450° C. to 900° C. Although higher temperature typically results in faster deposition, the faster deposition may result in crystal defects and film cracking.

In accordance with an embodiment, each of the bottom channel layers 107 has the same or substantially the same composition and size as one other, and each of the bottom sacrificial layers 105 also have the same or substantially the same composition and size as one another.

As used herein, “frontside or “first side” refers to a side on top of the semiconductor substrate 101 and/or in front of, on top of or in an upward direction from the gate and channel layers of the transistors in the orientation shown in the cross-sectional figures. As used herein, “backside” or “second side” refers to a side below the semiconductor substrate 101 and/or behind, below, or in a downward direction from the gate and channel layers of the transistors in the orientation shown in the cross-sectional figures (for example, opposite the “frontside”).

Portions of the stacked structure of the bottom sacrificial layers 105 and the bottom channel layers 107 are removed. Portions of the semiconductor substrate 101 are recessed to a lower height. Isolation regions 104 (e.g., shallow trench isolation (STI) regions) are formed in the recessed portions of the semiconductor substrate 101 and in the vacant areas left by the removal of the portions of the semiconductor substrate 101 between the remaining nanosheet stacks. The dielectric material may comprise, for example, SiN, SiON, SiCN, BN, SiBN, SiBCN, SiOCN, or combinations thereof, and is deposited using deposition techniques such as chemical vapor deposition (CVD), plasma-enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD).

The dummy gate portions 111 are formed on the uppermost bottom channel layers 107-3 and around the stacked structure of the bottom sacrificial layers 105 and the bottom channel layers 107. The dummy gate portions 111 include, but are not necessarily limited to, an amorphous silicon (a-Si) layer. The dummy gate portions 111 are deposited using deposition techniques such as CVD, PECVD, RFCVD, PVD, ALD, MBD, PLD, LSMCD, sputtering and/or plating, followed by a planarization process, such as chemical mechanical planarization (CMP), and lithography and etching steps to remove excess dummy gate material, and pattern the deposited layer.

Gate spacers 112 are formed on sides of the dummy gate portions 111 by one or more of the deposition techniques noted in connection with the deposition of the dummy gate material, for example. The material of the gate spacers 112 can comprise for example, one or more dielectrics, including, but not necessarily limited to, SiN, SiON, SiOC, SiCN, BN, SiBN, SiBCN, SiOCN, SiOₓ, or combinations thereof. The gate spacers 112 can be formed by any suitable technique such as deposition followed by directional etching. Deposition may include but is not limited to ALD or CVD. Directional etching may include but is not limited to, reactive ion etching (RIE).

The semiconductor structure 100 also includes sacrificial placeholders 122 and 123. The sacrificial placeholders 122 and 123 can be formed, for example, by removing portions of the bottom sacrificial layers 105, the bottom channel layers 107, and the BDI layer 109 in areas above where the sacrificial placeholders 122 and 123 are to be formed. The portions of the semiconductor substrate 101 between the stacked structures of the bottom sacrificial layers 105 and the bottom channel layers 107 and between the isolation regions 104 are then recessed, and the sacrificial placeholders 122 and 123 are disposed in and fill the trenches resulting from the recessing of the semiconductor substrate 101.

Due to, for example, germanium in the bottom sacrificial layers 105, lateral etching of the bottom sacrificial layers 105 can be performed selective to the bottom channel layers 107, such that the side portions of the bottom sacrificial layers 105 can be removed to create vacant areas to be filled in by inner spacers 113. The material of the inner spacers 113 can comprise, but is not necessarily limited to, a nitride such as SiN, SiON, SiCN, BN, SiBN, SiBCN, or SiOCN. Like the gate spacers 112, the inner spacers 113 can be formed by any suitable technique such as deposition followed by directional etching.

The source/drain regions 126 and 127 are formed above the sacrificial placeholders 122 and 123, respectively, and between the stacked structure of the bottom sacrificial layers 105 and the bottom channel layers 107. The isolation regions 104 are disposed around one or more sides of the sacrificial placeholders 122 and 123. Side surfaces of respective ones of the bottom channel layers 107 contact a side surface of at least one of the source/drain regions 126 and 127. In the case of n-type FETs (nFETs), the source/drain regions 126 and 127 can comprise silicon doped with n-type dopants including, for example, phosphorus (P), arsenic (As), and antimony (Sb). In the case of p-type FETS (pFETs), the source/drain regions 126 and 127 can comprise silicon doped with p-type dopants such as boron (B), boron fluoride (BF₂), gallium (Ga), indium (In), and thallium (Tl).

In illustrative embodiments, the sacrificial placeholders 122 and 123 can comprise, for example, SiGe, III-V semiconductor material or other suitable semiconductor material. The sacrificial placeholders 122 and 123 and their corresponding source/drain regions 126 and 127 can be epitaxially grown in a bottom-up epitaxial growth process. For example, the sacrificial placeholders 122 and 123 can be grown from the semiconductor substrate 101, and the source/drain regions 126 and 127 can be epitaxially grown from the exposed surfaces of their corresponding sacrificial placeholders 122 and 123.

An interlayer dielectric (ILD) layer 130 is formed to fill portions on and around the source/drain regions 126 and 127. The ILD layer 130 is deposited using deposition techniques such as, for example, CVD, PECVD, RFCVD, PVD, ALD, MBD, PLD, and/or LSMCD, followed by a planarization process, such as CMP, to remove excess portions of the ILD layer 130 and expose the dummy gate portions 111. The ILD layer 130 may comprise, for example, SiOx, SiOC, SiOCN, or some other dielectric.

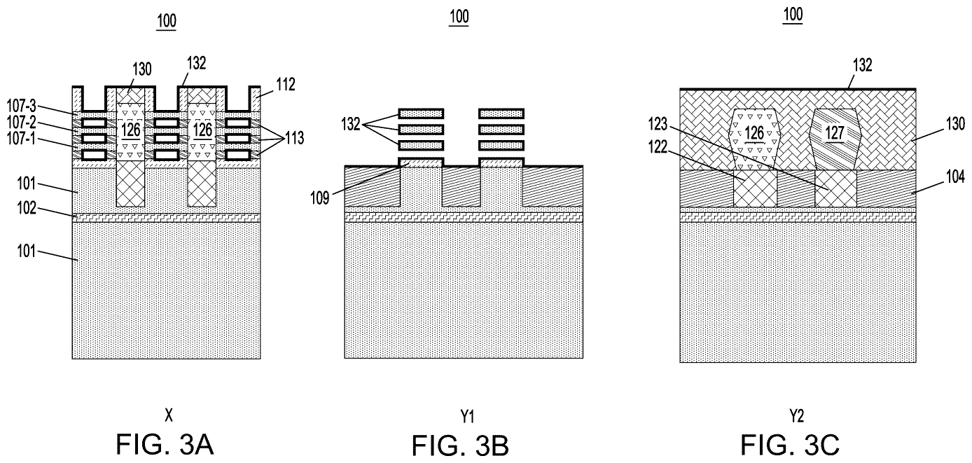

FIGS. 3A-3C show cross-sectional views, which correspond respectively to the lines X, Y1, and Y2 in FIG. 1, of the semiconductor structure 100 following removal of the dummy gate portions 111 and the bottom sacrificial layers 105, and formation of a high-k dielectric layer 132. For example, the dummy gate portions 111 can be selectively removed using hot ammonia to remove a-Si, and the bottom sacrificial layers 105 can be selectively removed with respect to the bottom channel layers 107 using, for example, a dry HCl etch.

Following removal of the dummy gate portions 111 and the bottom sacrificial layers 105, the bottom channel layers 107 are suspended. The high-k dielectric layer 132 is formed around the bottom channel layers 107 and covers the exposed surfaces of the isolation regions 104, BDI layer 109, the gate spacers 112, the inner spacers 113, and the ILD layer 130.

In some embodiments, the high-k dielectric layer 132 includes, but is not necessarily limited to, HfO₂ (hafnium oxide), ZrO₂ (zirconium dioxide), hafnium zirconium oxide, Al₂O₃ (aluminum oxide), and Ta₂O₅ (tantalum oxide). Examples of high-k materials also include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate.

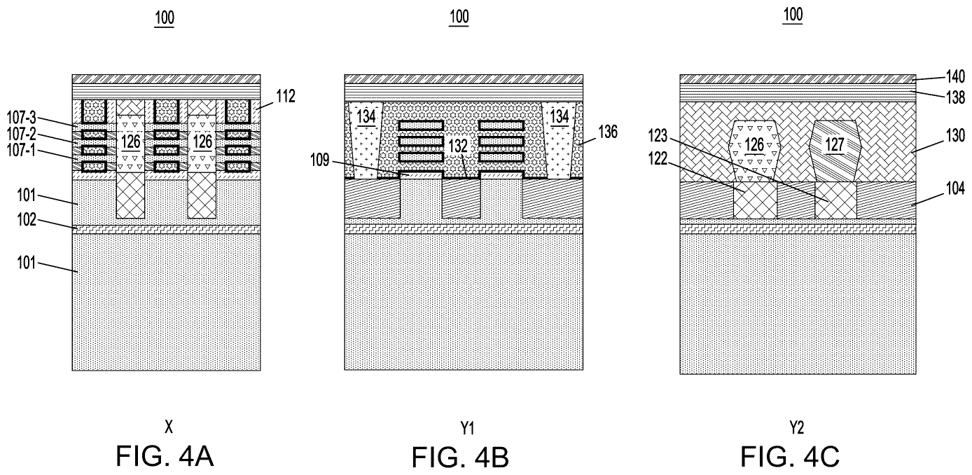

FIGS. 4A-4C show cross-sectional views, which correspond respectively to the lines X, Y1, and Y2 in FIG. 1, of the semiconductor structure 100 following formation of a reliability layer 136, gate cut regions 134, a first bonding layer 138, and an electromagnetic shield layer 140. The reliability layer 136 is formed on and around the bottom channel layers 107. In some embodiments, the reliability layer 136 can include, but is not necessarily limited to, a first layer comprising titanium nitride (TiN) and a second layer comprising amorphous silicon (a-Si). At least one embodiment includes performing a reliability anneal process to densify and crystallize the reliability layer 136, followed by a planarization process, such as CMP to remove excess reliability layer material and portions of the high-k dielectric layer 132 from the top of the semiconductor structure 100, as shown.

Portions of the reliability layer 136 and the high-k dielectric layer 132 are removed by a gate cut process to expose portions of the isolation regions 104. A dielectric material is deposited in the opening formed by the gate cut process to form the gate cut regions 134. The gate cut process can include one or more etching processes, such as RIE. The dielectric material of the gate cut regions 134 is deposited using deposition techniques such as, for example, CVD, PECVD, RFCVD, PVD, ALD, MBD, PLD, and/or LSMCD, followed by a planarization process, such as CMP, to remove excess portions of the dielectric material deposited on top of the reliability layer 136. The dielectric material of the gate cut regions 134 may comprise, but is not necessarily limited to, SiN, SiC, SiON, SiOC, SiCN, BN, SiBN, SiBCN, SiOCN, SiOₓ, or some other dielectric.

The first bonding layer 138 is deposited on top of the gate spacers 112, the ILD layer 130, the high-k dielectric layer 132, the gate cut regions 134, and the reliability layer 136. The first bonding layer 138 can be formed by depositing a dielectric bonding oxide material such as silicon dioxide, tetraethylorthosilicate (TEOS), or fluorinated tetraethylorthosilicate (FTEOS) using a deposition process (e.g., CVD or PECVD).

The electromagnetic shield layer 140 is formed on top of the first bonding layer 138 and can comprise a material for blocking electromagnetic interference and/or dissipating heat. In some embodiments, the electromagnetic shield layer 140 can correspond to a two-dimensional material. A two-dimensional material generally refers to a type of material with a thickness on an atomic scale (e.g., comprised of a single atom layer or a limited number of atom layers). In one embodiment, the two-dimensional material can be graphene, which may optionally be formed as a single layer of carbon atoms in a two-dimensional honeycomb lattice structure. In some embodiments, the two-dimensional material can have a thickness of 1 nm or less.

In at least one embodiment, an additional metal seed layer can be deposited on the first bonding layer 138 for graphene growth. Alternatively, the electromagnetic shield layer 140 can be epitaxially grown on a different substrate and then transferred to the first bonding layer 138.

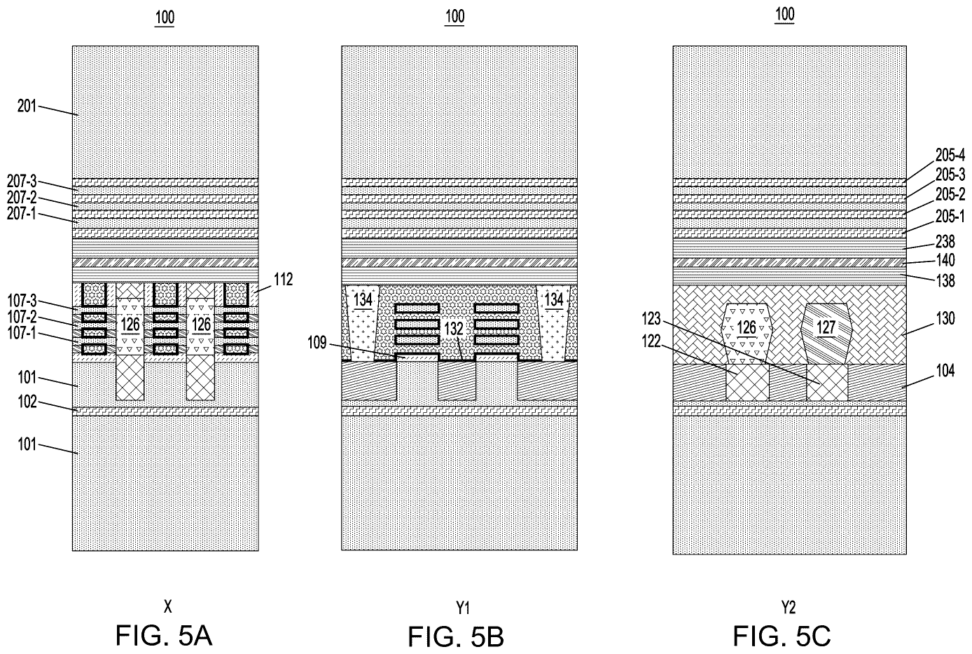

FIGS. 5A-5C show cross-sectional views, which correspond respectively to the lines X, Y1, and Y2 in FIG. 1, of the semiconductor structure 100 following bonding of an additional nanosheet stack comprising a top semiconductor substrate 201, top sacrificial layers 205-1, 205-2, 205-3 and 205-4 (collectively “top sacrificial layers 205”), top channel layers 207-1, 207-2, and 207-3 (collectively “top channel layers 207”), and a second bonding layer 238 for forming the top device level (see, e.g., FIGS. 6A-6C) of the semiconductor structure 100.

In some embodiments, the second bonding layer 238 is formed over the top semiconductor substrate 201, the top sacrificial layers 205, and the top channel layers 207. The second bonding layer 238 is then bonded to the electromagnetic shield layer 140.

It is to be appreciated that in other embodiments the electromagnetic shield layer 140, the first bonding layer 138, and the second bonding layer 238 can be formed in various other ways. For example, a first portion of the first bonding layer 138 can be formed, then the electromagnetic shield layer 140 can be formed on the first portion of the first bonding layer 138, and then a second portion of the first bonding layer 138 can be formed on the electromagnetic shield layer 140. The second bonding layer 238 is then bonded to the second portion of the first bonding layer 138, for example, using an oxide-oxide bonding process. As another example, a first portion of the second bonding layer 238 can be formed, then the electromagnetic shield layer 140 can be formed on the first portion of the second bonding layer 238, and then a second portion of the second bonding layer 238 can be formed on the electromagnetic shield layer 140. The second bonding layer 238 is then bonded to the first bonding layer 138. As yet another example, the electromagnetic shield layer 140 can be formed on the second bonding layer 238, and then the electromagnetic shield layer 140 can be bonded to the first bonding layer 138. The first bonding layer 138, the electromagnetic shield layer 140, and the second bonding layer 238 are collectively referred to herein as a “bonding structure”.

FIGS. 6A-6C show cross-sectional views, which correspond respectively to the lines X, Y1, and Y2 in FIG. 1, of the semiconductor structure 100 following formation of the top device level. Following the device bonding process, the top semiconductor substrate 201 over the stacked structure is removed, and the stacked structure is processed to form the semiconductor structure 100 as shown in FIGS. 6A-6C. More specifically, top gate spacers 212, top inner spacers 213, a top high-k dielectric layer 232, top source/drain regions 226 and 227, a top ILD layer 230, and top gate cut regions 234 can be formed using similar techniques and materials as described above for the corresponding elements that are below the first bonding layer 138.

The top device level of the semiconductor structure 100 also includes top gate structures 248. The top gate structures 248 can be formed following the formation of the top high-k dielectric layer 232 and in vacant areas left by removal of top dummy gate portions (not shown) and the top sacrificial layers 205. According to an embodiment, the top gate structures 248 each include a metal gate portion including a work-function metal (WFM) layer, including but not necessarily limited to, for a pFET, TiN, tantalum nitride (TaN), or ruthenium (Ru), and for an nFET, TiN, titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN, which can be deposited on the top high-k dielectric layer 232. The metal gate portions can also each further include a gate metal layer including, but not necessarily limited to, metals, such as tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the WFM layer and the top high-k dielectric layer 232. It should be appreciated that various other materials may be used for the metal gate portions as desired. A planarization process, such as CMP, can be performed to remove excess material of the top gate structures 248 and the top high-k dielectric layer 232 from the top surfaces of the top ILD layer 230 and the top gate spacers 212.

FIGS. 7A-7C show cross-sectional views, which correspond respectively to the lines X, Y1, and Y2 in FIG. 1, of the semiconductor structure 100 following formation of deep trenches 700 and shallow trenches 701. In some embodiments, additional dielectric material is deposited to extend the top ILD layer 230 above the top gate spacers 212, the top high-k dielectric layer 232, and the top gate cut regions 234. The deep trenches 700 are formed in the peripheral region of the semiconductor structure 100 (see, e.g., FIG. 1) and extend through the top ILD layer 230, the second bonding layer 238, the electromagnetic shield layer 140, the first bonding layer 138, and the ILD layer 130, and into the isolation regions 104, as shown.

The shallow trenches 701 are formed in the top ILD layer 230 to expose corresponding portions of the top gate structures 248 and the top source/drain regions 226 and 227. The deep trenches 700 and the shallow trenches 701 can be formed using one or more etching processes including dry etching processes such as RIE or ion beam etching (IBE), wet chemical etching processes, or a combination of these etching processes.

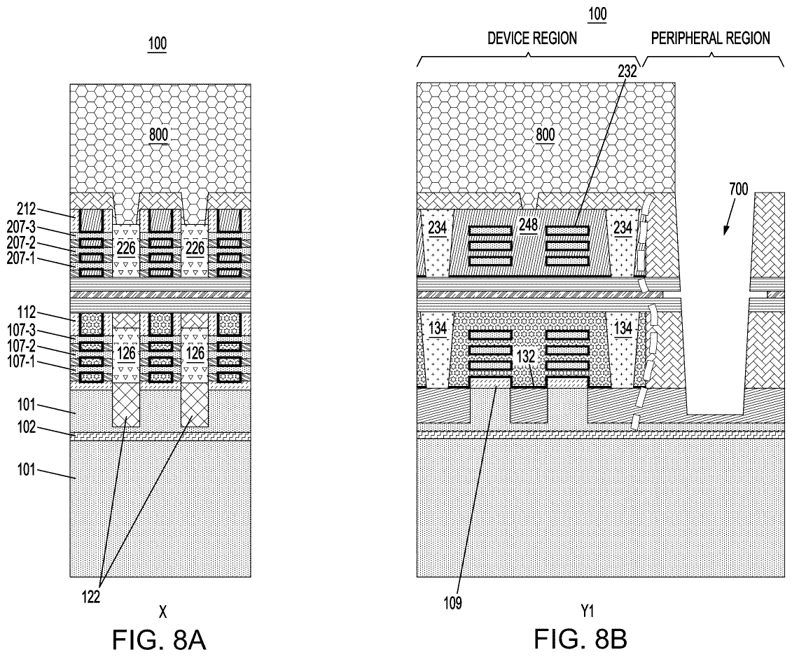

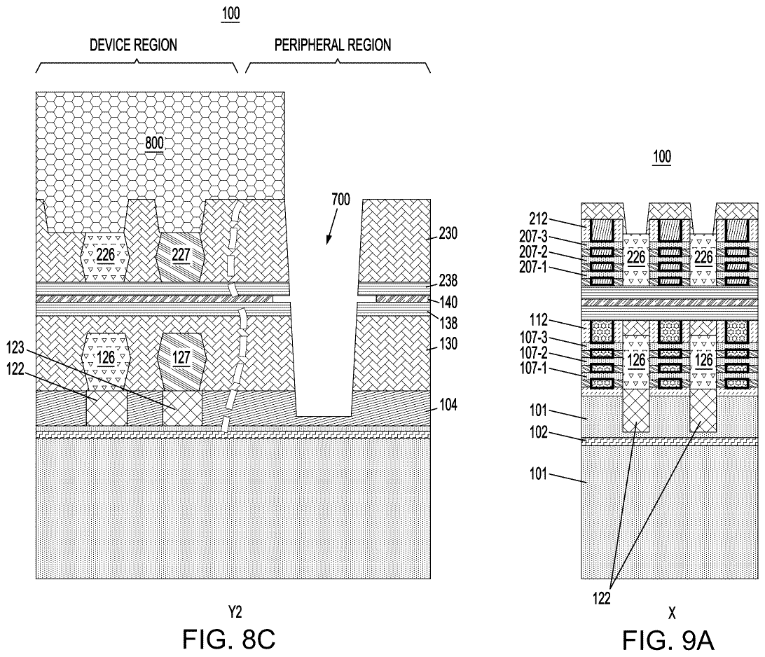

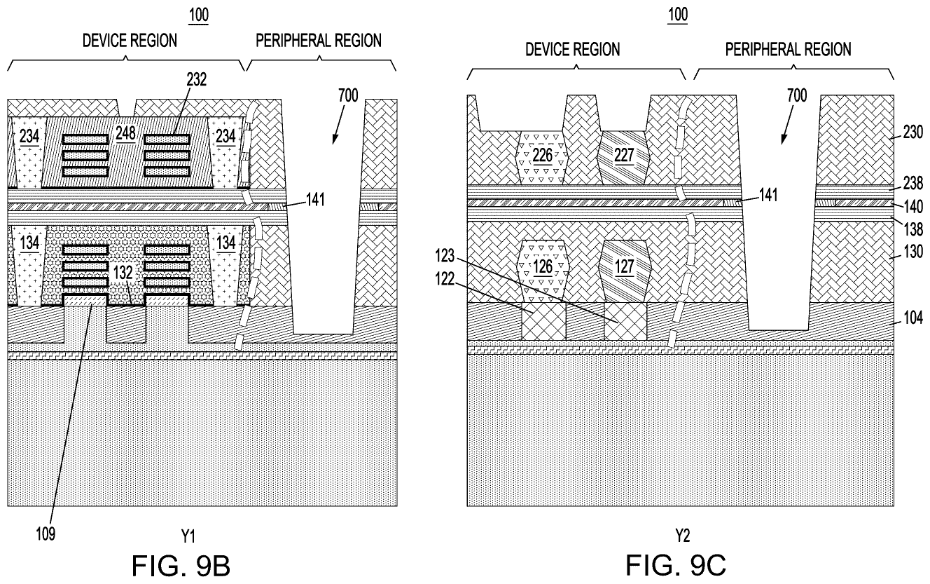

FIGS. 8A-8C show cross-sectional views, which correspond respectively to the lines X, Y1, and Y2 in FIG. 1, of the semiconductor structure 100 following partial removal of the electromagnetic shield layer 140. In some embodiments, portions of the electromagnetic shield layer 140 are removed by depositing and patterning an organic planarization layer (OPL) 800 on the top surface of the semiconductor structure 100 such that the deep trenches 700 remain. In some embodiments, the OPL 800 can be formed of an organic polymer such as carbon, hydrogen, and/or nitrogen, for example. An etching process is performed to selectively remove portions of the electromagnetic shield layer 140 exposed by the deep trenches 700, as shown in FIGS. 9B and 9C. The etching process used to remove the portions of the electromagnetic shield layer 140 can include a dry etching process (e.g., using oxygen plasma), a wet chemical etching process (e.g., using nitric acid or another suitable solution), a plasma or chemical based atomic layer etching (ALE) process, or a combination of these etching processes.

FIGS. 9A-9C show cross-sectional views, which correspond respectively to the lines X, Y1, and Y2 in FIG. 1, of the semiconductor structure 100 following formation of gate inner spacers 141. The material of the gate inner spacers 141 can comprise, but is not necessarily limited to, a nitride, such as, SiN, SiON, SiCN, BN, SiBN, SiBCN or SiOCN. Like the inner spacers 113, the gate inner spacers 141 can be formed by any suitable technique such as deposition followed by directional etching. An ashing process is also performed to remove the OPL 800. The ashing process strips the OPL 800 using, for example, oxygen plasma, nitrogen/hydrogen plasma or other carbon strip process.

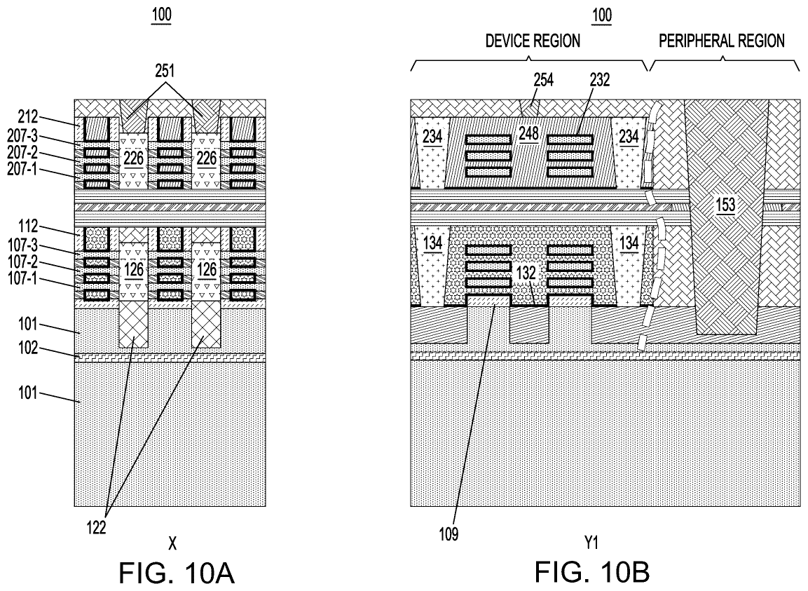

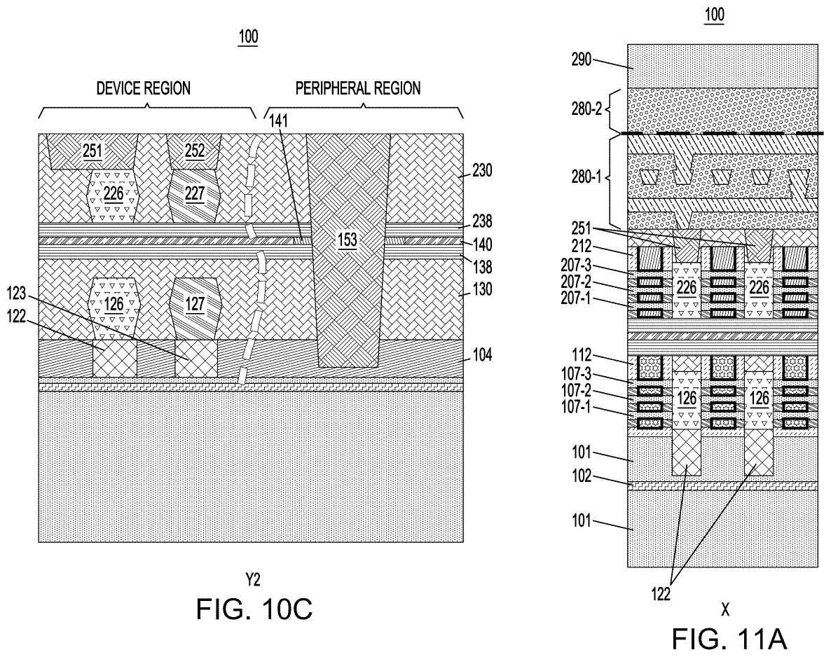

FIGS. 10A-10C depict cross-sectional views corresponding to the lines X, Y1, and Y2 in FIG. 1, following formation of frontside source/drain contacts 251 and 252, a frontside gate contact 254, and peripheral contacts 153. The frontside source/drain contacts 251 contact respective portions of the top source/drain region 226, and the frontside source/drain contacts 252 contact respective portions of the top source/drain region 227, as shown in FIGS. 10A and 10C.

The frontside source/drain contacts 251 and 252 are formed in the shallow trenches 701. Metal layers are deposited in the openings to form the frontside source/drain contacts 251 and 252. The metal layers comprise, for example, a silicide layer, such as Ni, Ti, NiPt, etc., a metal adhesion layer, such as TiN, and a conductive metal fill layer, such as W, Al, Co, Ru, etc., and can be deposited using, for example, a deposition technique such as CVD, PECVD, RFCVD, PVD, ALD, MBD, PLD, LSMCD, sputtering and/or plating, followed by a planarization process, such as CMP, to remove excess portions of the metal layers from on top of the top ILD layer 230.

The frontside gate contact 254 is formed through a portion of the top ILD layer 230 to land on and contact a corresponding one of the top gate structures 248. The process and materials used for forming the frontside gate contact 254 are similar to those used for forming the frontside source/drain contacts 251 and 252, for example.

The peripheral contacts 153 are formed in the deep trenches 700. The process and materials used for forming the peripheral contacts 153 are similar to those used for forming the frontside source/drain contacts 251 and 252, for example.

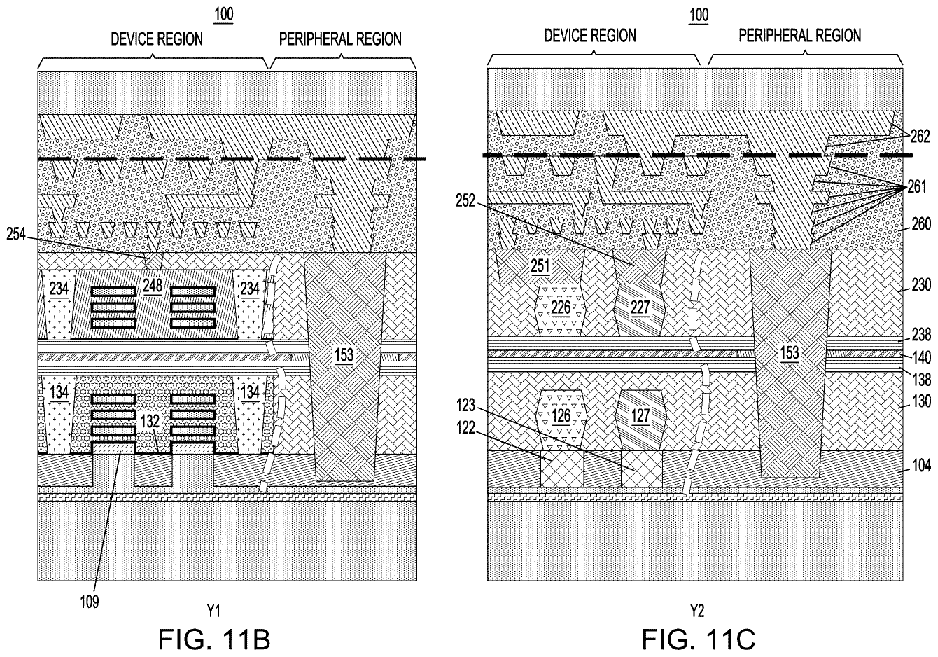

FIGS. 11A-11C show cross-sectional views, which correspond respectively to the lines X, Y1, and Y2 in FIG. 1, of the semiconductor structure 100 following formation of a first level of frontside BEOL interconnects 280-1 and a second level of frontside BEOL interconnects 280-2 (collectively “frontside BEOL interconnects 280”), and following formation of a carrier wafer 290.

The first level of frontside BEOL interconnects 280-1 are formed in one or more frontside ILD layers 260 and can comprise a first set of frontside interconnect layers 261. The second level of frontside BEOL interconnects 280-2 is formed above the first level of frontside BEOL interconnects 280-1 in the one or more frontside ILD layers 260 and can comprise a second set of frontside interconnect layers 262. The one or more frontside ILD layers 260 can be formed using similar techniques and materials as described for the ILD layer 130, for example.

In the example shown in FIGS. 11A-11C, the first level of frontside BEOL interconnects 280-1 contact the frontside source/drain contacts 251 and 252, the frontside gate contact 254, and the peripheral contacts 153. The first set and the second set of frontside interconnect layers 261 and 262 can be formed using similar techniques and materials as described for the frontside source/drain contacts 251 and 252, for example.

The carrier wafer 290 may be formed of materials similar to that of the semiconductor substrate 101 and may be formed over the second level of frontside BEOL interconnects 280-2 using a wafer bonding process, such as dielectric-to-dielectric bonding.

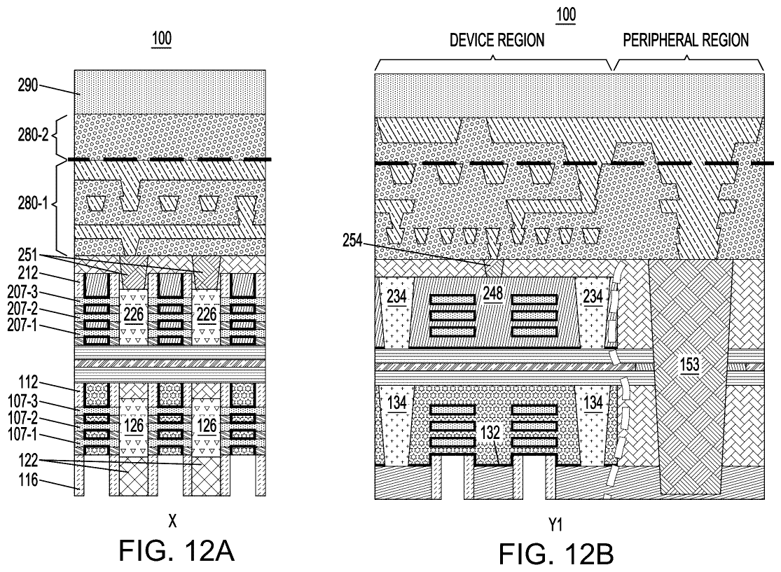

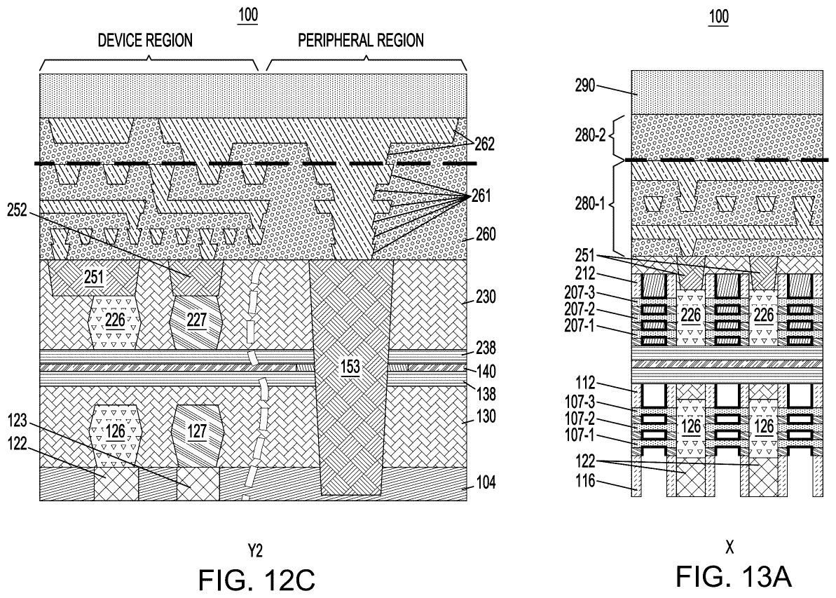

FIGS. 12A-12C show cross-sectional views, which correspond respectively to the lines X, Y1, and Y2 in FIG. 1, of the semiconductor structure 100 following wafer flipping, removal of the semiconductor substrate 101, the etch stop layer 102, and the BDI layer 109, and following formation of backside gate spacers 116. Using the carrier wafer 290, the semiconductor structure 100 may be “flipped” (for example, rotated 180 degrees) so that it is inverted, and the semiconductor substrate 101 and etch stop layer 102 are removed from the backside of the semiconductor structure 100. The semiconductor substrate 101 and the etch stop layer 102 may be removed using any suitable etch processing. For example, a first RIE may be used to partially remove the semiconductor substrate 101 up to the etch stop layer 102, a second RIE may be used to remove the etch stop layer 102, and a third RIE may be used to remove the remaining portions of the semiconductor substrate 101.

The exposed portions of the BDI layer 109 are removed selective to the high-k dielectric layer 132. The backside gate spacers 116 can then be formed using similar techniques and materials as described for the gate spacers 112, for example.

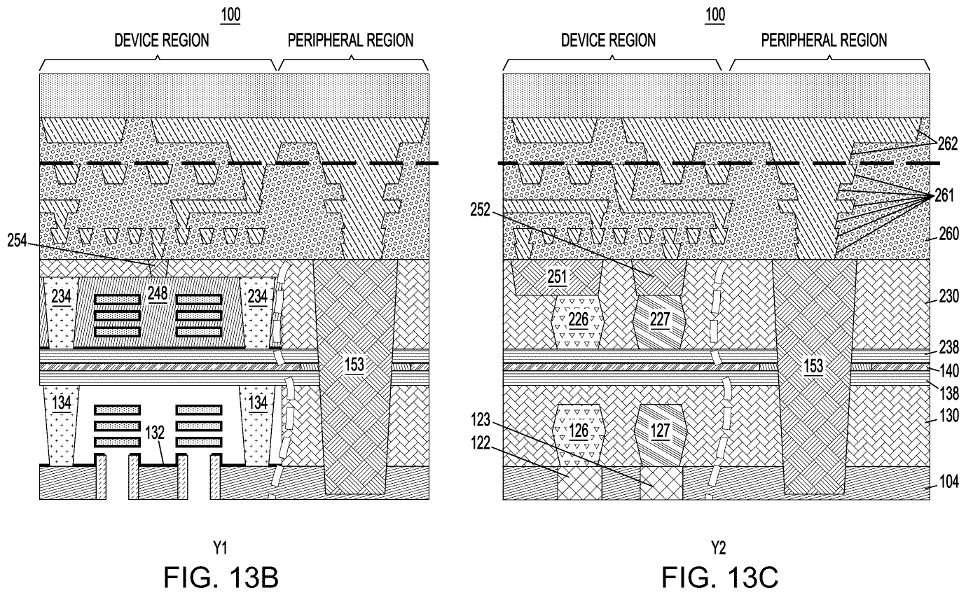

FIGS. 13A-13C show cross-sectional views, which correspond respectively to the lines X, Y1, and Y2 in FIG. 1, of the semiconductor structure 100 following removal of the exposed portions of the high-k dielectric layer 132 and removal of the reliability layer 136. The exposed portions of the high-k dielectric layer 132 can be removed using one or more etching processes, such as RIE. The reliability layer 136 can be selectively removed using hot ammonia, for example. Following removal of the reliability layer 136, the bottom channel layers 107 are suspended.

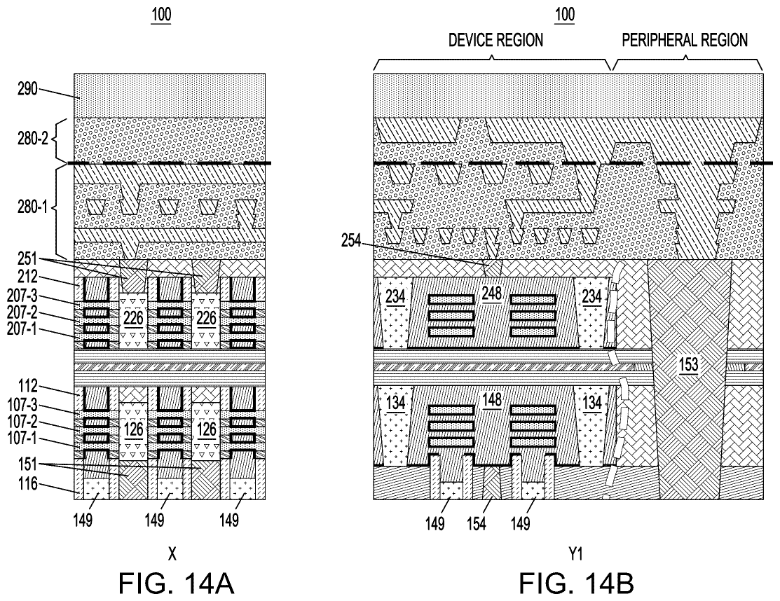

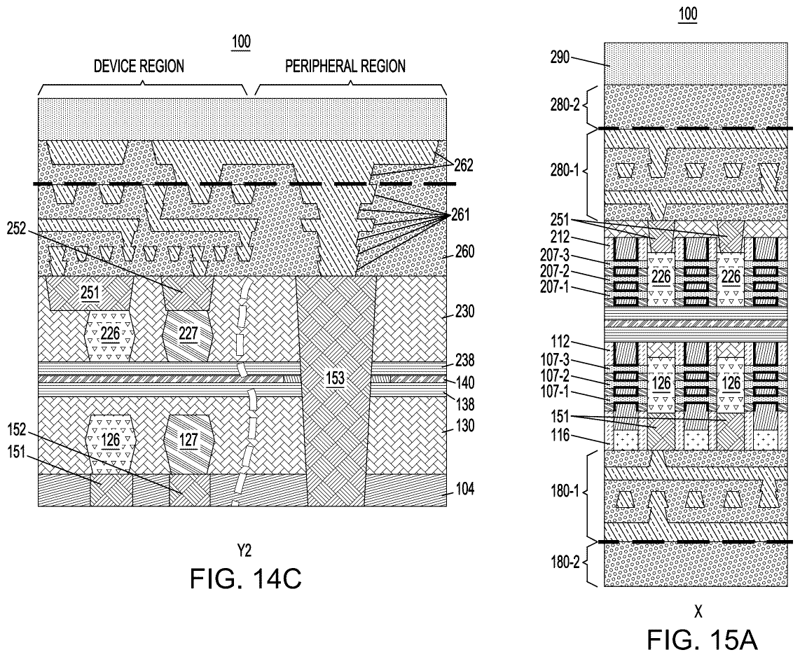

FIGS. 14A-14C show cross-sectional views, which correspond respectively to the lines X, Y1, and Y2 in FIG. 1, of the semiconductor structure 100 following formation of gate structures 148 for the bottom device level, recessing of the gate structures 148, formation of a capping layer 149, removal of the sacrificial placeholders 122 and 123, and backside contact formation.

The gate structures 148 are formed in the vacant areas left by the removal of the reliability layer 136 and between the backside gate spacers 116. The gate structures 148 can be formed using similar techniques and materials as the top gate structures 248, for example. The portions of the gate structures 148 between the backside gate spacers 116 are then recessed using, for example, selective dry and/or wet etch processes.

The capping layer 149 is formed to fill in the portions of the gate structures 148 that were removed. The capping layer 149 can comprise silicone (e.g., silicon nitride) or some other suitable capping layer material.

The backside contact formation can include removing the sacrificial placeholders 122 and 123, and forming backside source/drain contacts 151 and 152 in the vacant areas left by the removal of the sacrificial placeholders 122 and 123. The backside source/drain contacts 151 contact corresponding portions of the source/drain regions 126, and the backside source/drain contacts 152 contact corresponding portions of the source/drain regions 127. The backside source/drain contacts 151 and 152 can be formed using similar techniques and materials as the frontside source/drain contacts 251 and 252, for example.

A backside gate contact 154 is formed through a portion of the isolation regions 104 to contact a bottom surface of a corresponding one of the gate structures 148, as shown in FIG. 14B. The backside gate contact 154 can be formed using similar techniques and materials as the frontside gate contact 254, for example.

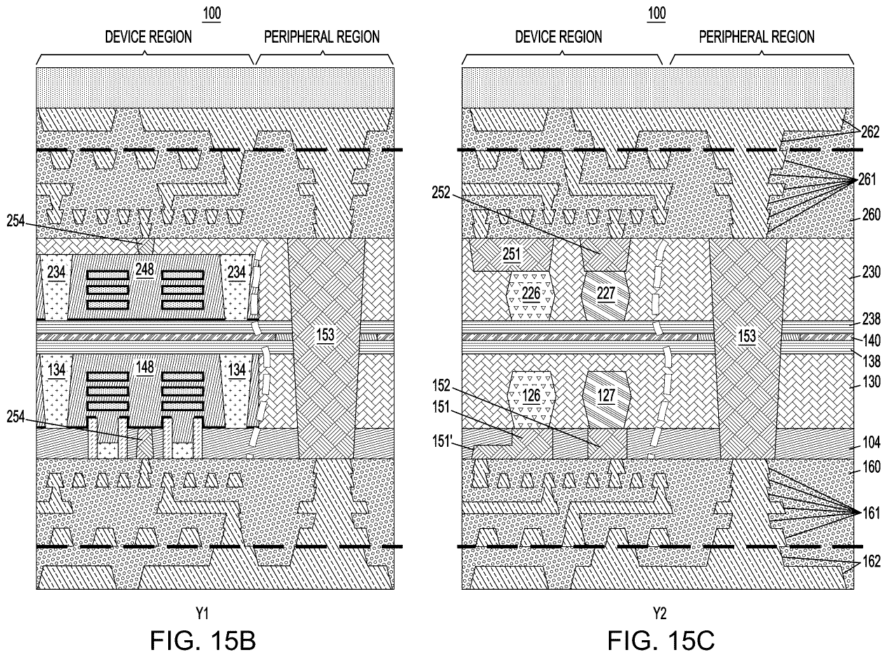

FIGS. 15A-15C show cross-sectional views, which correspond respectively to the lines X, Y1, and Y2 in FIG. 1, of the semiconductor structure 100 following formation of a first level of backside BEOL interconnects 180-1 and a second level of backside BEOL interconnects 180-2 (collectively “backside BEOL interconnects 180”).

The first level of backside BEOL interconnects 180-1 are formed in one or more backside ILD layers 160 and can comprise a first set of backside interconnect layers 161. The second level of backside BEOL interconnects 180-2 are formed below the first level of backside BEOL interconnects 180-1 in the one or more backside ILD layers 160 and can comprise a second set of backside interconnect layers 162. The one or more backside ILD layers 160 can be formed using similar techniques and materials as described for the ILD layer 130, for example.

In some embodiments, an extension 151′ can be added to one or more of the backside source/drain contacts 151 to facilitate connections with the first level of backside BEOL interconnects 180-1, as shown. In at least one embodiment, a thermal via (not shown) can be formed to contact the electromagnetic shield layer 140, which advantageously improves heat dissipation. The thermal via can be formed using similar techniques and materials as described for frontside source/drain contacts 251 and 252.

As shown in FIGS. 15A-15C, the second level of backside BEOL interconnects 180-2 is connected to the second level of frontside BEOL interconnects 280-2 via the peripheral contacts 153.

The backside BEOL interconnects 180 and the frontside BEOL interconnects 280 can include various interconnect structures, such as power rails and/or signal wirings. As a non-limiting example, the first set of backside interconnect layers 161 and/or the first set of frontside interconnect layers 261 can facilitate local connections, (e.g., connections to the bottom device level and/or the top device level of the semiconductor structure 100). The second set of backside interconnect layers 162 and/or the second set of frontside interconnect layers 262 can facilitate global connections (e.g., global power distribution elements, long distance signals, and/or long-distance clocking).

In at least one embodiment, the backside BEOL interconnects 180 can comprise backside power delivery network (BSPDN) layers that are formed on a backside power rail. BSPDN layers include various BSPDN structures such as, but not necessarily limited to, interconnects in a power supply path from voltage regulator modules (VRMs) to circuits. In such embodiments, the interconnects can comprise, for example, power and ground planes in circuit boards, cables, connectors and capacitors associated with a power supply. Backside power delivery can prevent BEOL routing congestion, resulting in power performance benefits.

Semiconductor devices and methods for forming the same in accordance with the above-described techniques can be employed in various applications, hardware, and/or electronic systems. Suitable hardware and systems for implementing embodiments may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments. Given the teachings provided herein, one of ordinary skill in the art will be able to contemplate other implementations and applications of embodiments.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to, CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher-level carrier) or in a multichip package (such as a ceramic carrier that has either or both surface interconnections or buried interconnections). In any case, the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

Conventional techniques for designing and fabricating semiconductor devices often fail to adequately address electromagnetic interference between vertically stacked transistors, particularly when power distribution and signal lines are routed in both the top and bottom device levels. Without in any way limiting the scope, interpretation, or application of the claims appearing below, a technical effect of one or more of the example embodiments disclosed herein is improving electromagnetic shielding and reducing interference by integrating a graphene layer between the bottom and top device levels during wafer bonding. These and other embodiments can effectively mitigate electromagnetic interference and/or improve heat dissipation while ensuring a reliable connection between higher-level frontside and backside BEOL interconnects.

In one embodiment, a semiconductor device includes a bottom transistor, a top transistor vertically stacked over the bottom transistor, and a bonding structure disposed between the bottom transistor and the top transistor. The bonding structure includes an electromagnetic shield layer. The semiconductor device further includes at least one peripheral contact positioned peripherally to the bottom transistor and the top transistor and extending through the bonding structure. The at least one peripheral contact is isolated from the electromagnetic shield layer of the bonding structure by one or more gate inner spacers.

The semiconductor device of the illustrative embodiment advantageously reduces electromagnetic interference between vertically stacked transistors by integrating the electromagnetic shield layer between the top and bottom transistors, which can effectively improve device reliability and performance relative to conventional techniques. The inclusion of one or more gate inner spacers isolates the peripheral contact from the electromagnetic shield layer, protecting against shorting issues without interrupting connections, for example, between backside and frontside interconnect layers.

In embodiments, the electromagnetic shield layer may include graphene. In such embodiments, the use of graphene provides a highly effective barrier against electromagnetic interference. The use of graphene also does not significantly add to the overall device height as it can be applied in a very thin layer (e.g., 1 nm or less).

In embodiments, the bonding structure may further include at least one bonding layer comprising a dielectric material.

In embodiments, the at least one peripheral contact may be connected to one or more frontside interconnect layers and one or more backside interconnect layers. In such embodiments, the peripheral contact can advantageously provide greater flexibility for distribution and/or signal routing for vertically stacked transistors.

In embodiments, the one or more frontside interconnect layers and/or the one or more backside interconnect layers may include one or more power rails and one or more signal wirings.

In embodiments, the semiconductor device may further include a carrier wafer positioned above the top transistor.

In embodiments, the one or more gate inner spacers may be positioned between the electromagnetic shield layer of the bonding structure and side surfaces of the at least one peripheral contact.

In embodiments, the bottom transistor and the top transistor each may include at least one complementary metal-oxide-semiconductor device.

In embodiments, the bottom transistor may include at least one gate structure, and the semiconductor device may further include at least one shallow trench isolation region, where a bottom surface of the at least one gate structure is positioned lower than a top surface of the at least one shallow trench isolation region.

In embodiments, a portion of the at least one gate structure that is positioned lower than the top surface of the at least one shallow trench isolation region may be positioned between adjacent backside gate spacers.

In embodiments, the semiconductor device may further include a capping layer positioned between the adjacent backside gate spacers and below the at least one gate structure.

In embodiments, the electromagnetic shield layer of the bonding structure may include a two-dimensional material.

In another embodiment, a semiconductor device includes a bottom device level including a first complementary metal-oxide-semiconductor device, a top device level including a second complementary metal-oxide-semiconductor device, and an electromagnetic shield layer positioned between the bottom device level and the top device level. The semiconductor device further includes one or more backside interconnect layers positioned adjacent to the bottom device level, one or more frontside interconnect layers positioned adjacent to the top device level, and at least one peripheral contact extending through the electromagnetic shield layer and connected to at least one of the one or more backside interconnect layers and at least one of the one or more frontside interconnect layers.

The semiconductor device of the illustrative embodiment advantageously reduces electromagnetic interference by integrating the electromagnetic shield layer between the top device level and the bottom device level, which can effectively improve device reliability and performance relative to conventional techniques.

In embodiments, the electromagnetic shield layer may include graphene. In such embodiments, the use of graphene provides a highly effective barrier against electromagnetic interference. The use of graphene also does not significantly add to the overall device height as it can be applied in a very thin layer (e.g., 1 nm or less).

In embodiments, the semiconductor device may further include at least one bonding layer comprising a dielectric material positioned between the bottom device level and the top device level, where the electromagnetic shield layer is formed in the at least one bonding layer.

In embodiments, the one or more backside interconnect layers and the one or more frontside interconnect layers may include one or more power rails and/or one or more signal wirings.

In embodiments, the at least one peripheral contact may be isolated from the electromagnetic shield layer by one or more gate inner spacers. In such embodiments, the inclusion of the one or more gate inner spacers isolates the peripheral contact from the electromagnetic shield layer, which protects against shorting issues without interrupting connections (e.g., between backside and frontside interconnect layers).

In yet another embodiment, a method includes forming a bottom transistor, forming a bonding structure over the bottom transistor, where the bonding structure includes an electromagnetic shield layer disposed between one or more bonding layers. The method further includes forming a top transistor over the bonding structure and forming at least one peripheral contact positioned peripherally to the bottom transistor and the top transistor and extending through the bonding structure, where the at least one peripheral contact is isolated from the electromagnetic shield layer of the bonding structure by one or more gate inner spacers.

The method of the illustrative embodiment advantageously reduces electromagnetic interference between vertically stacked transistors by integrating the electromagnetic shield layer between the top and bottom transistors, which can effectively improve device reliability and performance relative to conventional techniques. Additionally, the peripheral contact is isolated from the electromagnetic shield layer by one or more gate inner spacers, which protects against shorting issues without interrupting connections (e.g., between backside and frontside interconnect layers).

In embodiments, the method may further include removing one or more portions of the electromagnetic shield layer to form vacant areas and forming the one or more gate inner spacers in the vacant areas.

In embodiments, the method may further include forming one or more frontside interconnect layers and forming one or more backside interconnect layers. The one or more backside interconnect layers and the one or more frontside interconnect layers may each include one or more power rails and/or one or more signal wirings. The at least one peripheral contact may be connected to at least one layer of the one or more frontside interconnect layers and at least one layer of the one or more backside interconnect layers. In such embodiments, the peripheral contact can advantageously provide greater flexibility for distribution and/or signal routing in vertically stacked transistors.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times, and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments described herein have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a bottom transistor;
a top transistor vertically stacked over the bottom transistor;
a bonding structure disposed between the bottom transistor and the top transistor, wherein the bonding structure comprises an electromagnetic shield layer; and
at least one peripheral contact positioned peripherally to the bottom transistor and the top transistor and extending through the bonding structure, wherein the at least one peripheral contact is isolated from the electromagnetic shield layer of the bonding structure by one or more gate inner spacers.

2. The semiconductor device of claim 1, wherein the electromagnetic shield layer comprises graphene.

3. The semiconductor device of claim 1, wherein the bonding structure further comprises at least one bonding layer comprising a dielectric material.

4. The semiconductor device of claim 1, wherein the at least one peripheral contact is connected to one or more frontside interconnect layers and one or more backside interconnect layers.

5. The semiconductor device of claim 4, wherein the one or more frontside interconnect layers and/or the one or more backside interconnect layers comprise one or more power rails and one or more signal wirings.

6. The semiconductor device of claim 1, further comprising:
a carrier wafer positioned above the top transistor.

7. The semiconductor device of claim 1, wherein the one or more gate inner spacers are positioned between the electromagnetic shield layer of the bonding structure and side surfaces of the at least one peripheral contact.

8. The semiconductor device of claim 1, wherein the bottom transistor and the top transistor each comprise at least one complementary metal-oxide-semiconductor device.

9. The semiconductor device of claim 1, wherein the bottom transistor comprises at least one gate structure, and wherein the semiconductor device further comprises:
at least one shallow trench isolation region, wherein a bottom surface of the at least one gate structure is positioned lower than a top surface of the at least one shallow trench isolation region.

10. The semiconductor device of claim 9, wherein a portion of the at least one gate structure that is positioned lower than the top surface of the at least one shallow trench isolation region is positioned between adjacent backside gate spacers.

11. The semiconductor device of claim 10, further comprising:
a capping layer positioned between the adjacent backside gate spacers and below the at least one gate structure.

12. The semiconductor device of claim 1, wherein the electromagnetic shield layer of the bonding structure comprises a two-dimensional material.

13. A semiconductor device comprising:
a bottom device level comprising a first complementary metal-oxide-semiconductor device;
a top device level comprising a second complementary metal-oxide-semiconductor device;
an electromagnetic shield layer positioned between the bottom device level and the top device level;
one or more backside interconnect layers positioned adjacent to the bottom device level;
one or more frontside interconnect layers positioned adjacent to the top device level; and
at least one peripheral contact extending through the electromagnetic shield layer and connected to at least one of the one or more backside interconnect layers and at least one of the one or more frontside interconnect layers.

14. The semiconductor device of claim 13, wherein the electromagnetic shield layer comprises graphene.

15. The semiconductor device of claim 13, further comprising:
at least one bonding layer comprising a dielectric material positioned between the bottom device level and the top device level, wherein the electromagnetic shield layer is formed in the at least one bonding layer.

16. The semiconductor device of claim 13, wherein the one or more backside interconnect layers and the one or more frontside interconnect layers comprise one or more power rails and/or one or more signal wirings.

17. The semiconductor device of claim 16, wherein the at least one peripheral contact is isolated from the electromagnetic shield layer by one or more gate inner spacers.

18. A method comprising:
forming a bottom transistor;
forming a bonding structure over the bottom transistor, wherein the bonding structure comprises an electromagnetic shield layer disposed between one or more bonding layers;
forming a top transistor over the bonding structure; and
forming at least one peripheral contact positioned peripherally to the bottom transistor and the top transistor and extending through the bonding structure, wherein the at least one peripheral contact is isolated from the electromagnetic shield layer of the bonding structure by one or more gate inner spacers.

19. The method of claim 18, further comprising:
removing one or more portions of the electromagnetic shield layer to form vacant areas; and
forming the one or more gate inner spacers in the vacant areas.

20. The method of claim 18, further comprising:
forming one or more frontside interconnect layers; and
forming one or more backside interconnect layers;
wherein the one or more backside interconnect layers and the one or more frontside interconnect layers each comprise one or more power rails and/or one or more signal wirings, and wherein the at least one peripheral contact is connected to at least one layer of the one or more frontside interconnect layers and at least one layer of the one or more backside interconnect layers.
